(19) United States
(12) Patent Application Publication
(10) Pub. No.: US 2006/0187378 A1
(43) Pub. Date: Aug. 24, 2006

(54) Organic light emitting diode (OLED) backlight

(76) Inventors: Ban S. Bong, Calabasas, CA (US); Ragini Saxena, Simi Valley, CA (US)

Correspondence Address: SNELL & WILMER LLP, 600 ANTON BOULEVARD, SUITE 1400, COSTA MESA, CA, 92626, US

(21) Appl. No.: 11/062,195

(22) Filed: Feb. 18, 2005

(51) Int. Cl. G02F 1/1335

(52) U.S. Cl. 349/69

(57) ABSTRACT

The present invention is directed to the use of a plurality of OLED displays and a diffuser to form a display backlight. Such a backlight can be used as an AMLCD backlight. The OLED displays can support NVIS compatibility by reducing current provided to red sub-pixels, and by limiting transmission of light beyond 630 nm, possibly by material selection or filtering using thin film optical coatings.

### FIELD OF THE INVENTION

The present invention relates generally to backlights used in active matrix liquid crystal displays.

### BACKGROUND OF THE INVENTION

Transmissive and transflective active matrix liquid crystal displays (AMLCDs) typically comprise a backlight. In many instances the backlight is a cold cathode fluorescent lamp (CCFL) comprising a plurality of CCFL tubes. Unfortunately, displays comprising CCFL backlights are not appropriate for all applications, and cannot always be produced in desired sizes. Moreover, CCFL backlights have mercury (Hg) content which is considered a hazardous material and is not environmentally friendly. Additionally, CCFL backlights require high voltage, are bulky, and do not operate efficiently at cold temperatures

Organic light emitting diode (OLED) displays are emissive displays that utilize electroluminescent emission from thin solid films of organic material. These types of displays, being emissive, do not require a backlight. Unfortunately, large size OLED displays are currently difficult to produce.

### SUMMARY OF THE INVENTION

The present invention is directed to methods and apparatus for utilizing a plurality of organic light emitting diode (OLED) devices to backlight active matrix liquid crystal displays (AMLCDs).

In one embodiment, the present invention is an apparatus comprising a backlight, the backlight including a plurality of organic light emitting diode (OLED) devices arranged behind a diffuser.

In another embodiment, the present invention is an active matrix liquid crystal display apparatus including an active matrix liquid crystal display panel and a backlight assembly. The backlight assembly comprises at least one diffuser and a plurality of organic light emitting diode devices. The diffuser is positioned between the liquid crystal display panel and the plurality of organic light emitting diode devices.

In yet another embodiment, the invention is a method of backlighting an active matrix liquid crystal diode display where the method includes: (a) providing a plurality of organic light emitting diode displays; (b) providing a diffuser; and (c) arranging the plurality of OLED displays behind the diffuser such that the diffuser is positioned between the plurality of OLED displays and an active matrix liquid crystal display panel.

### BRIEF DESCRIPTION OF THE DRAWINGS

The exact nature of this invention, as well as the objects and advantages thereof, will become readily apparent from consideration of the following specification in conjunction with the accompanying drawings in which like reference numerals designate like parts throughout the figures thereof and wherein:

FIG. 1 is a schematic top view of an OLED backlight in accordance with an exemplary embodiment of the invention.

FIG. 2 is a schematic side view of the backlight of FIG. 1.

FIG. 3 is a schematic side view of an AMLCD in accordance with an exemplary embodiment of the invention.

FIG. 4 is a schematic side view of a first OLED display in accordance with an exemplary embodiment of the invention.

FIG. 5 is a schematic side view of a second OLED display in accordance with an exemplary embodiment of the invention.

FIG. 6 is a schematic side view of a third OLED display in accordance with an exemplary embodiment of the invention.

### DETAILED DESCRIPTION OF THE PREFERRED EMBODIMENTS

Reference will now be made to the preferred embodiments of the invention, examples of which are illustrated in the accompanying drawings. While the invention will be described in conjunction with the preferred embodiments, it will be understood that these embodiments are not intended to limit the invention. On the contrary, the invention is intended to cover alternatives, modifications and equivalents, which may be included within the spirit and scope of the invention as defined by the appended claims.

In the following detailed description, numerous specific details are set forth in order to provide a thorough understanding of the present invention. However, it will be understood by one of ordinary skill in the art that the present invention may be practiced without these specific details. In other instances, well known methods, procedures, components, and circuits have not been described in detail so as not to unnecessarily obscure the important aspects of the present invention.

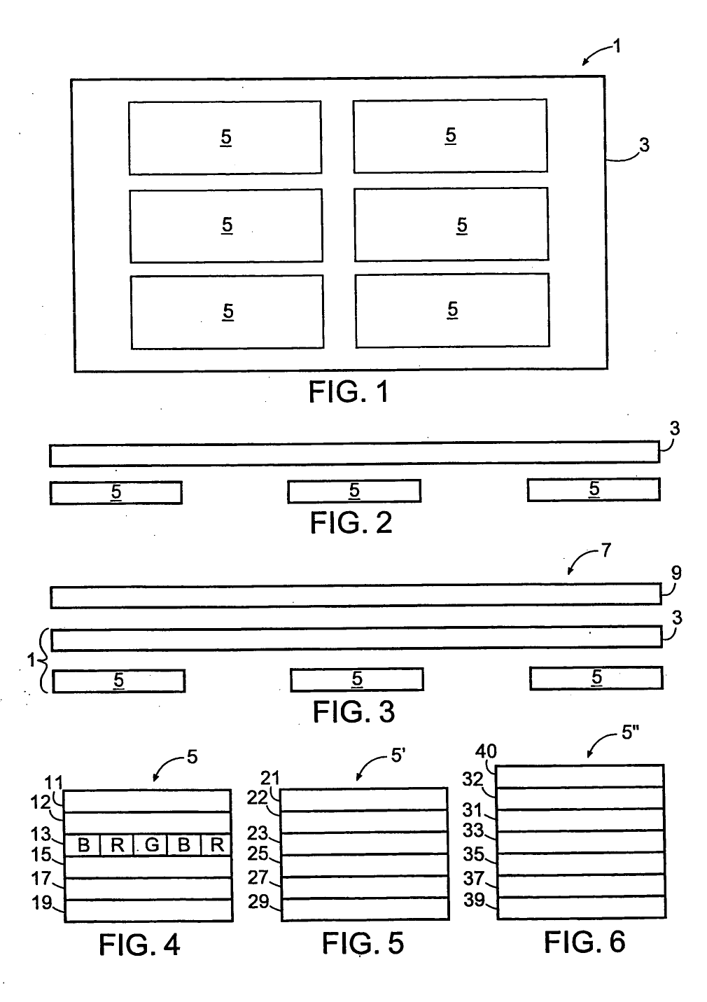

FIGS. 1 and 2 provide schematic views of an organic light emitting diode (OLED) backlight 1 that includes a diffuser 3 and a plurality of OLED displays 5. The OLED displays 5 produce light, and at least a portion of that light is transmitted through the diffuser 3. The diffuser 3 diffuses the light from the OLED displays/devices 5 sufficiently that variations in light emitted by the backlight as a result of spacing between the OLED displays is minimized or eliminated. As a result, the backlight emits a substantially uniform distribution of light from the surface of the diffuser 3 opposite the OLED displays 5.

The use of a plurality of OLED devices behind a diffuser as a backlight provides substantial redundancy. If an OLED device fails (and possibly if multiple OLED devices fail), the backlight 1 will continue to function. Light from any OLED devices that continue to function will be diffused by the diffuser 3 and emitted by the backlight 1.

The diffuser 3 may comprise any material or combination of materials; and/or may comprise a single unitary piece of material or an assembly of unitary pieces. However, regardless of the structure and materials used, it is preferred that the diffuser 3 operate to minimize or eliminate any non-uniformities in light caused by the spacing apart of the OLED displays 5 and/or differences in illumination levels provided by the OLED displays 5. It is contemplated that a light transmitting diffuser comprising a polymerized high diffusion polymer such as a Clarex® DR-III CV Light Diffusion Filter may be advantageously used as the diffuser 3. It is contemplated that the use of such diffusers will compensate for OLED displays that are positioned such that a gap separates adjacent OLED displays. It is also contemplated that the use of such diffusers will compensate for OLED displays that are positioned such that a gap of at least ten percent of the width of the largest of two adjacent OLED displays separates the OLED displays.

The OLED displays 5 may comprise any type of OLED display device. However, it is preferred that the OLED displays 5 be adapted and/or controlled for night vision (NVIS) compatibility as will be discussed further. The number and arrangement of OLED displays 5 within a backlight 1 may vary between embodiments. However, it is contemplated that backlights 1 will generally comprise a plurality of OLED displays 5, and in some instances will comprise at least X displays where X is one of 2, 4, 8, 16, and 32. Moreover, the arrangement of the OLED displays 5 within the backlight 1 will vary between embodiments. However, it is contemplated that they will be generally positioned such that they are substantially planar, i.e. at a common distance from the diffuser 3. In some instances the OLED displays 5 may be arranged as shown in FIG. 1, i.e. in rows and columns where all the rows include an equal number of OLED displays 5, and all the columns include and equal number of OLED displays 5. However, it is contemplated that some embodiments may comprise alternative arrangements of OLED displays 5.

In FIG. 3, an AMLCD module 7 includes the backlight 1 and an AMLCD panel 9 with the diffuser 3 positioned between the OLED displays 5 and the AMLCD panel 9. Light from the backlight 1 passes through the AMLCD panel 9, with the AMLCD selectively transmitting, blocking, or modifying the light passing through it to display an image to a person viewing the AMLCD module 7.

It is contemplated that the AMLCD panel 9 may comprise any type of AMLCD panel. As such, it may include one or more of the following: LCD layer; common electrode; pixel electrodes; TFT thin film transistors; source lines; glass; anti-reflective coating; anti-glare coating; polarizer film; alignment layers; and color filters. In some instances the AMLCD panel 9 may be directly coupled to the diffuser 3. In other instances it may be separated from diffuser 3, possibly with one or more other components positioned between the diffuser 3 and the AMLCD panel 9.

Although the AMLCD panel 9 may comprise any size, it is contemplated that the methods and apparatus described herein support large AMLCDs. As such, it is contemplated that the different AMLCD panels 9 may be sized to have a diagonal measure of at least Y inches where Y is one of: 4, 8, 12, 16, 20, 24, 28, 32, 40, and 60.

It is preferred that the AMLCD module 7 be night vision imaging system (NVIS) compatible. As a result, it is preferred that substantially all of the light emitted by the display module 7 have a wavelength less than or equal to 630 nm. This can be accomplished in any reasonable manner, but it is preferred that it be accomplished in one of three ways: (1) when OLED displays comprising colored sub-pixels are used, reducing the current provided to red sub-pixels; (2) when “white” OLED displays are used, choosing an organic emitter layer which emits little, if any, light having a wavelength above 630 nm; and (3) utilizing one or more filters to ensure that substantially all the light emitted by the backlight 1 has a wavelength less than or equal to 630 nm.

In FIG. 4, an OLED display 5 includes a glass substrate 11, an anode 12, a hole injection layer 13, an organic emitter layer 15, an electron transport layer 17, and a cathode 19. The organic emitter layer 15 includes a plurality of red (R), green (G), and blue (B) sub-pixels. It is contemplated that a display such as the display module 7 may utilize a backlight 1 comprising OLED displays 5 such as those shown in FIG. 4. In such an instance, the display module 7 may be made NVIS compatible by providing it with a controller that controls the current provided to each sub-pixel and to reduce or eliminate the current provided to the red sub-pixels in order to decrease the emission of light above 630 nm by the OLED displays 5.

In FIG. 5, an OLED display 5 includes includes a glass substrate 21, an anode 22, a hole injection layer 23, an organic emitter layer 25, an electron transport layer 27, and a cathode 29. The OLED display 5 of FIG. 5 is adapted to not emit light beyond 630 nm. It is adapted by utilizing an organic emitter layer 25 that emits little if any light beyond 630 nm.

In FIG. 6, an OLED display 5 an OLED display 5 includes includes a glass substrate 31, an anode 32, a hole injection layer 33, an organic emitter layer 35, an electron transport layer 37, a cathode 39, and a filter layer 40. The OLED display 5 of FIG. 6 is adapted to not emit light beyond 630 nm in that includes a filter layer 40 that reduces or eliminates the amount of light emitted by OLED display 5 having a wavelength above 630 nm.

Although described in regards to a wavelength limit of 630 nm, it is contemplated that alternative embodiments may have different wavelength limits. As such, some embodiments may be adapted to reduce or eliminate light emissions above one or more of the following wavelengths: 550 nm, 575 nm, 600 nm, 650 nm, and 700 nm.

It is also contemplated that in may be beneficial to adapt any AMLCD modules 7 as described herein such that they emit substantially no infrared and/or ultraviolet light. Such adaptation could be accomplished by utilizing OLED displays 5 such as described in relation to FIGS. 4-6, and/or by using one or more filters to filter light emitted by the backlight 1 and/or the display module 7.

In some instances, such AMLCD modules 7 and/or OLED backlights 1 may have at least two operating states during which the plurality of OLED displays emit light. In such instances a first operating state may correspond to a day time visibility mode, and a second operating state may correspond to a NVIS mode. For embodiments that utilize current changes to red sub pixels to change modes, switching between the first operating state and the second operating state while a pattern displayed by the LCD display remains constant causes the current provided to red sub-pixels of the display to vary to a greater extent than it causes current provided to non-red sub pixels to vary.

What is claimed is:

1. An apparatus comprising a backlight, the backlight including a plurality of organic light emitting diode (OLED) devices arranged behind a diffuser.

2. The apparatus of claim 1 wherein the apparatus is a liquid crystal display (LCD).

3. The apparatus of claim 2 wherein the apparatus is an active matrix liquid crystal display (AMLCD).

4. The apparatus of claim 2 wherein the diffuser separates the plurality of organic light emitting diode (OLED) devices from a liquid crystal display (LCD).

5. The apparatus of claim 4 wherein the apparatus has at least two operating states during which the plurality of OLED displays emit light, wherein switching between the first operating state and the second operating state while a pattern displayed by the LCD display remains constant causes the current provided to red sub-pixels of the display to vary to a greater extent than it causes current provided to non-red sub pixels to vary.

6. The apparatus of claim 4 wherein the OLED displays are adapted to minimize light emissions above 630 nm.

7. The apparatus of claim 4 wherein the OLED displays each comprise a filter layer between a white light emitting layer and the diffuser.

8. The apparatus of claim 4 wherein the OLED displays each comprise a light emitting layer where substantially all of the light emitted from the light emitting layer has a wavelength less than 630 nm.

9. The apparatus of claim 2 wherein the LCD has a diagonal measurement of at least 10 inches.

10. The apparatus of claim 1 wherein the backlight does not emit infrared light.

11. The apparatus of claim 1 wherein the backlight does not emit ultra violet light.

12. The apparatus of claim 1 wherein the OLED displays are positioned such that a gap separates adjacent OLED displays, and the width of the gap between any two OLED displays is at least 0.2 inches.

13. The apparatus of claim 1 wherein the OLED displays are positioned such that a gap separates adjacent OLED displays, and the width of the gap between any two adjacent OLED displays is at least 10% of the width of the two adjacent OLED displays.

14. An active matrix liquid crystal display module comprising:
an active matrix liquid crystal display panel; and
a backlight assembly; wherein
the backlight assembly comprises at least one diffuser and a plurality of organic light emitting diode devices; and
the diffuser is positioned between the liquid crystal display panel and the plurality of organic light emitting diode devices.

15. The apparatus of claim 14 wherein substantially all of the light emitted by the display has a wavelength of less than 630 nm.

16. A method of backlighting an active matrix liquid crystal diode display comprising:
providing a plurality of organic light emitting diode displays;
providing a diffuser; and
arranging the plurality of OLED displays behind the diffuser such that the diffuser is positioned between the plurality of OLED displays and an active matrix liquid crystal display panel.

17. The method of claim 16 further comprising:
reducing the amount of current provided to red sub-pixels of the OLED displays to place the display in a night time visibility mode.

18. The method of claim 16 further comprising:
increasing the amount of current provided to red sub-pixels of the OLED displays to place the display in a day time visibility mode.
